(19) United States
(12) Patent Application Publication
(10) Pub. No.: US 2010/0321093 A1
(43) Pub. Date: Dec. 23, 2010

(54) REFERENCE VOLTAGE OUTPUT CIRCUIT

(75) Inventor: Shigeru Nagatomo, Miyazaki (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/816,427

(22) Filed: Jun. 16, 2010

(30) Foreign Application Priority Data
Jun. 19, 2009 (JP) 2009-146684

(51) Int. Cl. H01L 23/34

(52) U.S. Cl. 327/513

(57) ABSTRACT

A first output section of a reference voltage output circuit outputs a negative gradient voltage of a first magnitude. An amplifier includes a non-inverting input terminal connected to the first output section, an inverting input terminal, and an output terminal. One end of a first resistor connected to the output terminal and the other end connected to the inverting input terminal. One end of a second resistor is connected to the other end of the first resistor. A second output section connected to the other end of the second resistor outputs a negative gradient voltage of a second magnitude having an absolute value greater than the first magnitude. A resistance value ratio of the first and second resistors is set such that a temperature gradient of the voltage applied to the first resistor is a positive gradient having an absolute value of the same magnitude as the first magnitude.

### CROSS-REFERENCE TO RELATED APPLICATION

This application claims priority under 35 USC 119 from Japanese Patent Application No. 2009-146684 filed on Jun. 19, 2009, the disclosure of which is incorporated by reference herein.

### BACKGROUND OF THE INVENTION

1. Field of the Invention

The present invention relates to a reference voltage output circuit that outputs a reference voltage that does not fluctuate according to changes in temperature.

2. Related Art

Generally, a band gap circuit that cancels of the temperature dependency of a reference voltage is employed when a reference voltage that does not fluctuate according to changes in temperature is required.

A band gap circuit, for example, uses a circuit employing a diode, a circuit combining the negative thermal voltage of a transistor with the positive thermal voltage of a resistor, or other such circuits. Furthermore, circuits that combine the voltage generated by the above circuits together with an operational amplifier, in order to impart current capability, are also employed.

For example, as a reference voltage generation circuit that generates a reference voltage that does not fluctuate according to changes in temperature, there is a voltage generation circuit described in Japanese Patent Application Laid-Open (JP-A) No. 2000-235423. This voltage generation circuit includes a V_{T} generation circuit which commonly connects emitters of a pair of transistors whose current densities are different, and generates a voltage corresponding to a difference between the base voltage and the emitter voltage which is proportional to temperature T, a non-linear Δ Vbe generation circuit that receives the output of the V_{T} generation circuit, generates ΔVbe having a current density ratio proportional to temperature, multiplies Δ Vbe m times and outputs the result, and a Vref output circuit that allows a constant currents Ic to flow in a transistor, adds a base-emitter voltage Vbe of this transistor to the output of the non-linear Δ Vbe generation circuit, and outputs the result. Configuration is thereby made such that an output voltage equal to a band gap voltage can be obtained from the Vref output circuit.

However, in the reference voltage generation circuit described in JP-A No. 2000-235423, while a reference voltage that does not fluctuate according to changes in temperature can be generated, the configuration of the circuit is complicated.

### SUMMARY

The present invention provides a reference voltage output circuit that suppresses temperature fluctuations in voltage output from an amplifier using a simple circuit configuration.

A first aspect of the present invention is a reference voltage output circuit including: a first voltage output section including a voltage output terminal that outputs a voltage having a negative temperature gradient of a first magnitude; an amplifier including a non-inverting input terminal that is connected to the voltage output terminal, an inverting input terminal, and amplified voltage output terminal that outputs an amplified voltage; a first resistor including a first end connected to the amplified voltage output terminal and a second end connected to the inverting input terminal; a second resistor including a first end connected to a second end of the first resistor; and a second voltage output section that is connected to the second end of the second resistor and that outputs a voltage having a negative temperature gradient of a second magnitude having an absolute value that is greater than an absolute value of the first magnitude, wherein a ratio of a resistance value of the first resistor to a resistance value of the second resistor is set as a value such that a temperature gradient of the voltage applied to the first resistor is a positive temperature gradient value and has an absolute value of the same magnitude as the absolute value of the first magnitude.

According to the aspect, the second voltage output section that is being connected to the second end of the second resistor outputs voltage having a negative temperature gradient of the second magnitude, with an absolute value that is greater than the first magnitude of negative temperature gradient of the voltage output from the first voltage output section. Furthermore, the ratio of the resistance value of the first resistor to the resistance value of the second resistor is determined as a value such that the temperature gradient of the voltage applied to the first resistor has a positive temperature gradient and the absolute value thereof has the same magnitude as that of the first magnitude. Consequently, a voltage having a positive temperature gradient with an absolute value that is the same magnitude as the first magnitude is applied to the first resistor.

A voltage having the same magnitude as the voltage applied to the non-inverting input terminal is applied to the inverting input terminal of the amplifier. Namely, the inverting input terminal is applied with a voltage having a negative temperature gradient of the first magnitude.

Consequently, according to the reference voltage output circuit of the present aspect, since the negative temperature gradient of the voltage applied to the inverting input terminal and the positive temperature gradient of the voltage applied to the first resistor cancel each other out, temperature fluctuations in the voltage output from the amplifier can be suppressed using a simple circuit configuration. Furthermore, due to the circuit configuration of the reference voltage output circuit being simplified, the power consumption of the reference voltage output circuit is reduced.

In the above aspect, the second voltage output section may be a transistor operating in a saturated region.

As explained above, in the present aspect, temperature fluctuations in the voltage output from an amplifier can be suppressed using a simple circuit configuration.

### BRIEF DESCRIPTION OF THE DRAWINGS

An exemplary embodiment of the present invention will be described in detail based on the following figures, wherein:

FIG. 1 is a schematic diagram of a reference voltage output circuit according to the present exemplary embodiment; and

FIG. 2 is a graph showing an example of voltage output from an operational amplifier of the reference voltage output circuit as a result of a simulation.

### DETAILED DESCRIPTION

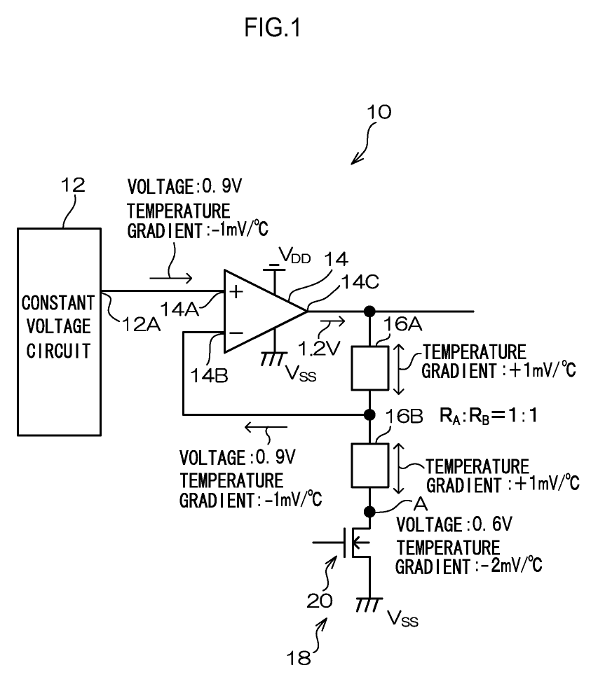

FIG. 1 shows a configuration of a reference voltage output circuit 10 according to the present exemplary embodiment.

The reference voltage output circuit 10 is equipped with a constant voltage circuit 12, an operational amplifier 14, a resistor 16A, a resistor 16B, and a voltage output section 18. The constant voltage circuit 12 outputs a voltage having a negative temperature gradient of a first magnitude from a voltage output terminal 12A. The operational amplifier 14 includes a non-inverting input terminal 14A that is connected to the voltage output terminal 12A of the constant voltage circuit 12, an inverting input terminal 14B, and an amplified voltage output terminal 14C that outputs an amplified voltage (reference voltage). A first end of the resistor 16A is connected to the amplified voltage output terminal 14C of the operational amplifier 14, and the second end thereof is connected to the inverting input terminal 14B of the operational amplifier 14. The first end of the resistor 16B is connected to the second end of the resistor 16A. The voltage output section 18 is connected to the second end of the resistor 16B, and outputs a voltage having a negative temperature gradient of a second magnitude that has an absolute value larger than the first magnitude.

The constant voltage circuit 12 according to the present exemplary embodiment outputs from the voltage output terminal 12A, for example, a voltage having a first magnitude and negative temperature gradient of −1 mV/° C. and thus, when the temperature is 25° C., outputs a voltage of 0.9V. Namely, the first magnitude according to the present exemplary embodiment is 1 mV, and the voltage output from the constant voltage circuit 12 falls by 1 mV for each rise in temperature of 1° C.

The voltage of 0.9 V at a temperature of 25° C., having the temperature gradient of −1 mV/° C., which has been output from the voltage output terminal 12A of the constant voltage circuit 12, is applied to the non-inverting input terminal 14A of the operational amplifier 14 according to the present exemplary embodiment. Therefore, the voltage applied to the inverting input terminal 14B of the operational amplifier 14 is the same magnitude as the voltage applied to the non-inverting input terminal 14A, which is 0.9V at a temperature of 25° C., and has the temperature gradient of −1 mV/° C.

The operational amplifier 14 is equipped with two power supply terminals for supplying power. A high power supply voltage VDD (for example a voltage of 1.2 V or greater) is applied to one of the power supply terminals, and a low power supply voltage VSS (for example ground voltage) is applied to the other power supply terminal.

The voltage output section 18 according to the present exemplary embodiment is configured with an N channel MOSFET (NMOS) transistor 20, with the drain terminal thereof connected to the resistor 16B, and the low power supply voltage VSS applied to the source terminal thereof. A voltage to operate the NMOS transistor 20 in a saturated region is applied to the gate terminal thereof. Since the NMOS transistor 20 may be operated in the saturated region, a diode connection (in which the drain terminal and the gate terminal are connected) may be employed.

The voltage output from the drain terminal of the NMOS transistor 20 operating in the saturated region (the voltage at point A in FIG. 1, referred to below as “drain voltage”) is generally about 0.6V in an NMOS transistor fabricated from silicon, and generally has a temperature gradient of −2 mV/° C. Namely, the above second magnitude according to the present exemplary embodiment is 2 mV, and the drain voltage output from the NMOS transistor 20 falls by 2 mV for every 1° C. rise in temperature.

In the reference voltage output circuit 10 according to the present exemplary embodiment, the ratio of a resistance value R_{A} of the resistor 16A to a resistance value R_{B} of the resistor 16B is set to a value such that the temperature gradient of the voltage applied to the resistor 16A has a positive temperature gradient and the absolute value thereof has the same magnitude as the first magnitude. In this manner, the value of the ratio of the resistance value R_{A} of the resistor 16A to the resistance value R_{B} of the resistor 16B is determined to be the value such that the temperature gradient of the voltage applied to the resistor 16A has a positive temperature gradient and the absolute value thereof has the same magnitude as the first magnitude. Consequently, the negative temperature gradient of the voltage applied to the inverting input terminal 14B and the positive temperature gradient applied to the resistor 16A cancel each other out.

In the reference voltage output circuit 10 according to the present exemplary embodiment, since the temperature gradient of the voltage applied to the non-inverting input terminal 14A and to the inverting input terminal 14B is −1 mV/° C., the ratio of the resistance value R_{A} of the resistor 16A to the resistance value R_{B} of the resistor 16B is set to a value such that the temperature gradient of the voltage applied to the resistor 16A is +1 mV/° C.

Given that the temperature gradient of the drain voltage of the NMOS transistor 20 is dVₜ, the temperature gradient of the voltage applied to the resistor 16A is dV_{A}, and the temperature gradient of the voltage applied to the resistor 16B is dV_{B}, then, since the NMOS transistor 20, the resistor 16A, and the resistor 16B are connected together in series, the relationship between temperature gradient dVₜ, temperature gradient dV_{A}, and temperature gradient dV_{B} is as shown by Equation (1).

dVₜ=−(dV_{A}+dV_{B}) (1)

In the present exemplary embodiment, since the temperature gradient dVₜ of the drain voltage of the NMOS transistor 20 is −2 mV/° C., according to Equation (1), the sum of the temperature gradient dV_{A} of the voltage applied to the resistor 16A and the temperature gradient dV_{B} of the voltage applied to the resistor 16B is +2 mV/° C. Furthermore, in the present exemplary embodiment, since the temperature gradient dV_{A} of the voltage applied to the resistor 16A is +1 mV/° C., the temperature gradient dV_{B} of the voltage applied to the resistor 16B is +1 mV/° C.

The ratio of the resistance value R_{A} of the resistor 16A to the resistance value R_{B} of the resistor 16B can be computed by substituting the values of temperature gradient dV_{A} of the voltage applied to the resistor 16A and temperature gradient dV_{B} of the voltage applied to the resistor 16B in the following Equation (2).

R_{A}/R_{B}=dV_{A}/dV_{B} (2)

According to Equation (2), in the present exemplary embodiment in which the temperature gradient dV_{A} of the voltage applied to the resistor 16A is set to +1 mV/° C., the ratio of the resistance value R_{A} of the resistor 16A to the resistance value R_{B} of the resistor 16B is computed as 1:1. Therefore, in the reference voltage output circuit 10 according to the present exemplary embodiment, resistances are employed for the resistor 16A and the resistor 16B such that the ratio of the resistance value R_{A} to the resistance value R_{B} is 1:1.

The voltage output from the reference voltage output circuit 10 having a band gap circuit configured as described above by the NMOS transistor 20 and the resistor 16A and resistor 16B, namely the reference voltage output from the amplified voltage output terminal 14C of the operational amplifier 14, is 1.2V. Furthermore, operation of the operational amplifier 14 is facilitated by setting the voltage output from the constant voltage circuit 12 to a smaller voltage (0.9V in the present exemplary embodiment) than the voltage output from the amplified voltage output terminal 14C of the operational amplifier 14.

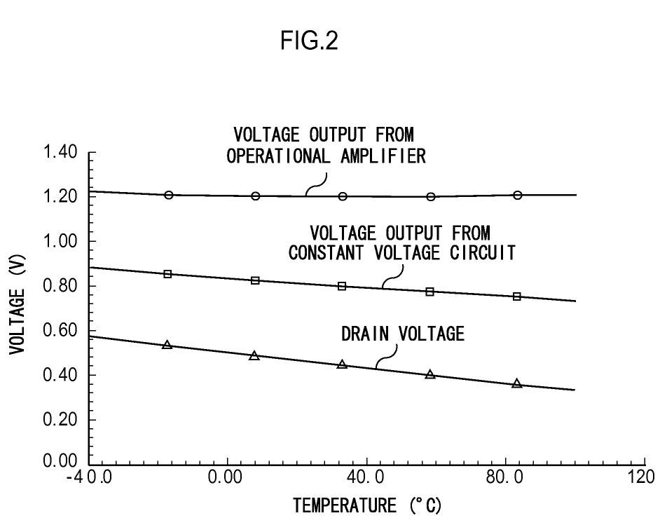

FIG. 2 shows an example of simulation results of the voltage output from the operational amplifier 14 of the reference voltage output circuit 10 according to the present exemplary embodiment. The horizontal axis of FIG. 2 shows the temperature, and the vertical axis shows the voltage. Further, FIG. 2 shows a negative temperature gradient for the temperature fluctuations of voltage output from the constant voltage circuit 12, and a negative temperature gradient for the temperature fluctuations in drain voltage.

As shown in FIG. 2, it can be seen that the voltage output from the operational amplifier 14 is substantially a constant value, even in the presence of a temperature dependent reduction in the voltage output from the constant voltage circuit 12.

As explained in detail above, the reference voltage output circuit includes a first voltage output section (the constant voltage circuit 12 in the present exemplary embodiment) that outputs a voltage having a negative temperature gradient of a first magnitude (1 mV in the present exemplary embodiment) from its voltage output terminal, an amplifier (the operational amplifier 14 in the present exemplary embodiment) having a non-inverting terminal, inverting terminal, and amplified voltage output terminal for outputting an amplified voltage, a first resistor (the resistor 16A in the present exemplary embodiment), and a second resistor (the resistor 16B in the present exemplary embodiment). The voltage output terminal of the first voltage output section is connected to the non-inverting terminal of the amplifier. A first end of the first resistor is connected to the amplified voltage output terminal, and the second end of the first resistor is connected to the inverting input terminal. A first end of the second resistor is connected to the second end of the first resistor.

The second voltage output section (the transistor 20 in the present exemplary embodiment), which is connected to the second end of the second resistor, outputs a voltage having a negative temperature gradient of a second magnitude (2 mV in the present exemplary embodiment) having an absolute value greater than a first magnitude of negative temperature gradient in the voltage output from the first voltage output section. Furthermore, the ratio of the first resistor to the second resistor is set as a value such that the temperature gradient of the voltage applied to the first resistor has a positive temperature gradient and the absolute value thereof has the same magnitude as the first magnitude, so that the negative temperature gradient of the voltage applied to the inverting input terminal and the positive temperature gradient of the voltage applied to the first resistor, cancel each other out. Consequently, temperature fluctuations in the voltage output from the amplifier can be suppressed with a simple circuit configuration. Furthermore, since circuit configuration of the reference voltage output circuit is simplified, power consumption of the reference voltage output circuit is reduced.

What is claimed is:

1. A reference voltage output circuit comprising:
a first voltage output section including a voltage output terminal that outputs a voltage having a negative temperature gradient of a first magnitude;
an amplifier including a non-inverting input terminal that is connected to the voltage output terminal, an inverting input terminal, and amplified voltage output terminal that outputs an amplified voltage;
a first resistor including a first end connected to the amplified voltage output terminal and a second end connected to the inverting input terminal;
a second resistor including a first end connected to a second end of the first resistor; and
a second voltage output section that is connected to the second end of the second resistor and that outputs a voltage having a negative temperature gradient of a second magnitude having an absolute value that is greater than an absolute value of the first magnitude,
wherein a ratio of a resistance value of the first resistor to a resistance value of the second resistor is set as a value such that a temperature gradient of the voltage applied to the first resistor is a positive temperature gradient value and has an absolute value of the same magnitude as the absolute value of the first magnitude.

2. The reference voltage output circuit of claim 1, wherein the second voltage output section comprises a transistor operating in a saturated region.
